(19) United States
(12) Patent Application Publication
(10) Pub. No.: US 2012/0302025 A1
(43) Pub. Date: Nov. 29, 2012

(54) Method for Manufacturing a Semiconductor Structure

(75) Inventors: Haizhou Yin, Poughkeepsie, NY (US); Huilong Zhu, Poughkeepsie, NY (US); Zhijiong Luo, Poughkeepsie, NY (US)

(73) Assignee: INSTITUTE OF MICROELECTRONICS, CHINESE ACADEMY OF SCIENCES, Beijing (CN)

(21) Appl. No.: 13/380,517

(22) PCT Filed: Aug. 25, 2011
(86) PCT No.: PCT/CN11/78876

§ 371 Date: Dec. 22, 2011

(30) Foreign Application Priority Data
May 27, 2011 (CN) 201110141244.8
Aug. 25, 2011 (CN) PCT/CN2011/078876

(51) Int. Cl. H01L 21/336

(52) U.S. Cl. 438/287; 438/303; 257/E21.409

(57) ABSTRACT

The present application provides a method for manufacturing a semiconductor structure, which comprises following steps: providing a substrate; forming a gate dielectric layer on the substrate; forming a dummy gate structure on the gate dielectric layer, wherein the dummy gate is formed from a polymer material; implanting dopants into portions of the substrates on opposite sides of the dummy gate structure to form source/drain regions; removing the dummy gate; annealing the source/drain regions to activate the dopants; and forming a metal gate. According to the present invention, it is proposed to manufacture a dummy gate structure with a polymer material, which significantly simplifies the subsequent etching process for removing the dummy gate structure and alleviates the etching difficulty accordingly.

The present application claims priority benefit of Chinese Patent application No. 201110141244.8 titled “Method for Manufacturing a Semiconductor Structure” filed on 27 May 2011, which is herein incorporated by reference in its entirety.

### FIELD OF THE INVENTION

The present invention relates to semiconductor manufacturing field, more particularly, to a method for manufacturing a semiconductor structure.

### BACKGROUND OF THE INVENTION

With development in semiconductor manufacturing industry, integrated circuits with better performance and more powerful functions require greater element density, thus sizes of and spaces between components have to be further scaled down (which nowadays has already reached 45 nm or below). Accordingly, requirements of process control during manufacturing a semiconductor device are increasingly specified. However, in many cases, a balance has to be reached between the specific requirements at respective processing steps, such that an optimized effect of process control is realized accordingly.

In a traditional Gate Replacement Process for semiconductor manufacturing, poly-silicon materials are widely used to manufacture dummy gate structures. Although poly-silicon materials may sustain high temperatures, which therefore guarantee the dummy gate structures against damage due to annealing of the device, the poly-silicon materials are too rigid to be removed and cause etching problem when the dummy gate structures are removed.

Therefore, it is necessary to provide a method for manufacturing a semiconductor structure, which is capable of effectively alleviating the difficulty when etching dummy gates.

### SUMMARY OF THE INVENTION

The present invention aims to provide a method for manufacturing a semiconductor structure, which is favorable for alleviating difficulty when removing dummy gate structures at a Gate Replacement Process.

In one aspect, the present invention provides a method for manufacturing a semiconductor structure, which comprises:

(a) providing a substrate;

(b) forming a gate dielectric layer on the substrate, and forming a dummy gate structure on the gate dielectric layer; wherein the dummy gate structure is formed from a polymer material;

(c) implanting dopants into portions of the substrates on opposite sides of the dummy gate structure to form source/drain regions;

(d) removing the dummy gate structure;

(e) annealing the source/drain regions to activate the dopants;

(f) forming a metal gate.

As compared to the prior art, the method for manufacturing a semiconductor structure provided by the present invention exhibits following advantages: in formation of a dummy gate structure, materials such as poly-silicon and amorphous silicon used in the conventional process are replaced by a polymer material. Because poly-silicon is too rigid to etch, once a dummy gate structure is manufactured from a polymer material as proposed by the present invention, it becomes easy to etch the dummy gate away so as to form a gate structure. Accordingly, the steps involved in etching a dummy gate are effectively simplified, and the technical difficulty of removing a dummy gate structure is alleviated as well.

### BRIEF DESCRIPTION OF THE DRAWINGS

Other characteristics, objectives and advantages of the present invention are made more evident according to perusal of the following detailed description of exemplary embodiment(s) in conjunction with accompanying drawings.

FIG. 1 illustrates a flowchart of a method for manufacturing a semiconductor structure according to an embodiment of the present invention;

FIG. 2 to FIG. 8 illustrate cross-sectional structural diagrams of a semiconductor structure at respective stages of the method for manufacturing a semiconductor structure according to the flowchart of the embodiment of the present invention as shown in FIG. 1;

Same or similar reference signs in the accompanying drawings denote same or similar elements.

### DETAILED DESCRIPTION OF THE INVENTION

Objectives, technical solutions and advantages of the present invention are made more evident according to the following detailed description of exemplary embodiments in conjunction with the accompanying drawings.

Embodiments of the present invention are described in detail here below, wherein examples of the embodiments are illustrated in the drawings, in which same or similar reference signs throughout denote same or similar elements or elements have same or similar functions. It should be appreciated that the embodiments described below in conjunction with the drawings are illustrative, and are provided for explaining the prevent invention only, thus shall not be interpreted as limitations to the present invention.

Various embodiments or examples are provided here below to implement different structures of the present invention. To simplify the disclosure of the present invention, description of the components and arrangements of specific examples is given below. Of course, they are illustrative only and not limiting the present invention. Moreover, in the present invention, reference numbers and/or letters may be repeated in different embodiments. Such repetition is for the purpose of simplification and clearness, yet does not denote the relationship between respective embodiments and/or arrangements being discussed. Furthermore, the present invention provides various examples for various process and materials. However, it is obvious for a person of ordinary skill in the art that other processes and/or materials may alternatively be utilized. In addition, the following structure in which a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. It is noteworthy that the component(s) illustrated in the drawings may not be drawn to scale. The description of the conventional components, processing technology and crafts are omitted herein in order not to limit the present invention unnecessarily.

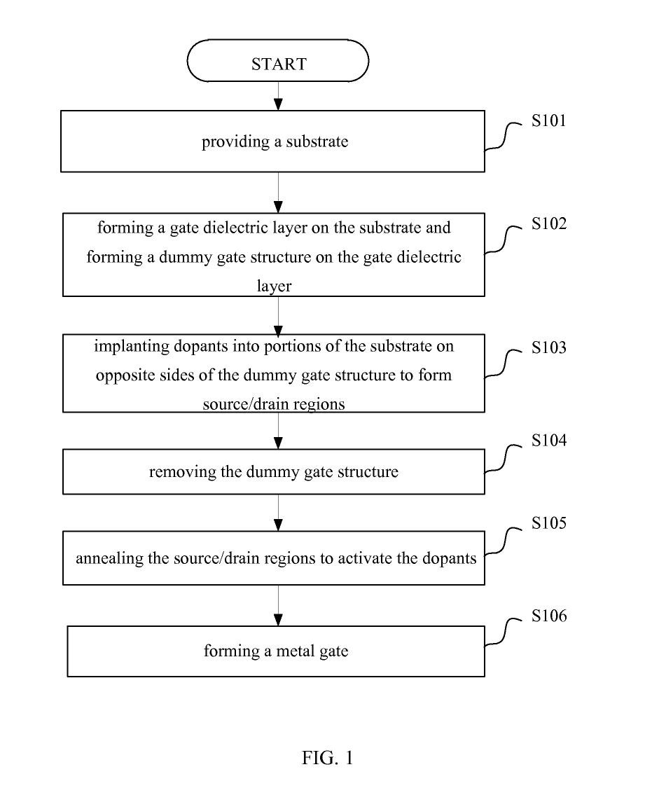

With reference to FIG. 1, which illustrates a flowchart of a method for manufacturing a semiconductor structure according to an embodiment of the present invention, the method comprises:

at step S101, providing a substrate;

at step S102, forming a gate dielectric layer on the substrate, and forming a dummy gate structure on the gate dielectric layer; wherein the dummy gate structure is formed from a polymer material;

at step S103, implanting dopants into portions of the substrates on opposite sides of the dummy gate structure to form source/drain regions;

at step S104, removing the dummy gate structure;

at step S105, annealing the source and drain regions to activate the dopants;

at step S106, forming a metal gate.

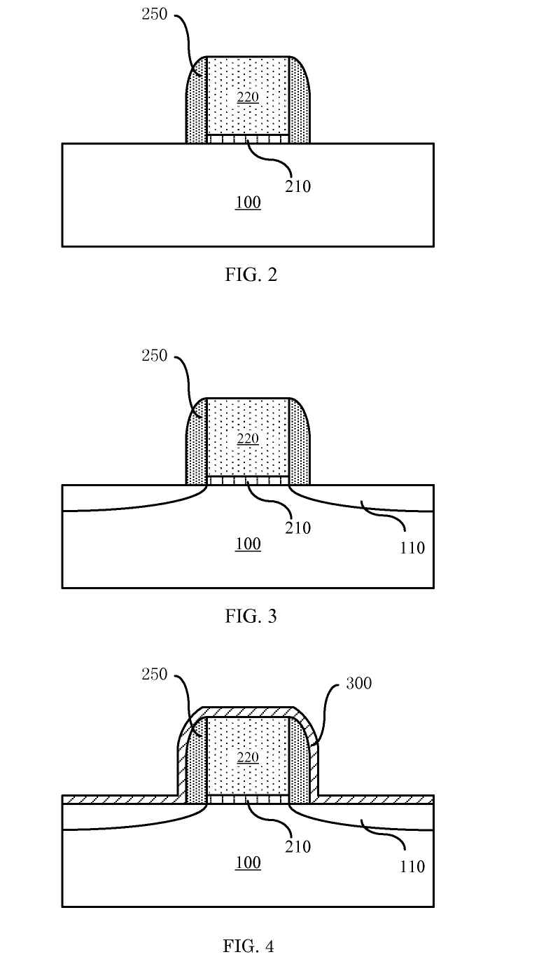

Steps S101 through S106 are described here below in conjunction with FIG. 2 to FIG. 8, which illustrate cross-sectional structural diagrams of a semiconductor structure at respective stages of the method for manufacturing a semiconductor structure according to the flowchart shown in FIG. 1, in view of various embodiments of the present invention. It is noteworthy that the drawings for respective embodiments are illustrative only, thus are not necessarily drawn to scale.

At step S101, a substrate 100 is provided. The substrate 100 may be a silicon substrate (e.g. a silicon wafer). According to design requirement in the prior art (e.g. a P-type substrate or a N-type substrate), the substrate 100 may be of various doping configurations. The substrate 100 in other embodiments may further include other basic semiconductors, for example germanium. Alternatively, the substrate 100 may comprise a compound semiconductor, such as SiC, GaAs, InAs or InP. Typically, the substrate 100 may have but not limited to a thickness of around several hundred micrometers, which for example may be in the range of 400 μm-800 μm.

At step S102, a gate dielectric layer 210 is formed on the substrate 100. The gate dielectric layer 210 may be a thermal oxide layer, consisted of SiO, or Si₂N₂O, for example, or may comprise a high-k dielectric, for example, at least one material selected from a group consisting of HfAlON, HfSiAlON, HfTaAlON, HfTiAlON, HfON, HfSiON, HfTaON, HfTiON, Al₂O₃, La₂O₃, ZrO₂ and LaAlO. The thickness of the gate dielectric layer 210 may be 1 nm-10 nm, for example, 3 nm, 5 nm or 8 nm. It is applicable to form the gate dielectric layer 210 by means of Thermal Oxidation, Chemical Vapor Deposition (CVD), Atomic Layer Deposition (ALD), etc.

A dummy gate structure 220 is formed on the gate dielectric layer 210, wherein the dummy gate structure 220 is formed from a polymer material, which may be at least one material selected from a group consisting of Polymethylmethacrylate (PMMA), polycarbonate, SU-8, Polydimethylsiloxane (PDMS), Polyimide and Parylene. Deposition, CVD or the like may be utilized to form the dummy gate structure. For example, deposition is adopted, if SU-8 is selected for manufacturing the dummy gate structure 220. Since Polyimide is a kind of photoresist, thus in case it is selected for manufacturing the dummy gate structure 220, then spin coating, and exposing and developing method may be adopted.

Optionally, sidewall spacers 250 may be formed on sidewalls of the gate stack for isolating the gate. The sidewall spacers 250 may be formed from at least one material selected from a group consisting of Si₃N₄, SiO₂, Si₂N₂O, and SiC, and/or other material as appropriate. The sidewall spacers 250 may be in a multi-layer structure. The sidewall spacers 250 may be formed through depositing and etching process, and its thickness may be in the range of 10 nm-100 nm, for example, 30 nm, 50 nm or 80 nm, as shown in FIG. 2.

At step S103, source/drain regions 110 are formed. As shown in FIG. 3, the source/drain regions 110 may be formed through implanting P-type or N-type dopants into portions of the substrate 100; for example, for PMOS, the source/drain regions 110 may comprise P-type doped SiGe; for NMOS, the source/drain regions 110 may comprise N-type doped Si. The source/drain regions 110 may be formed by way of lithography, ion implantation, diffusion and/or any other method as appropriate. In the present embodiment, the source/drain regions 110 are located within the substrate 100, while in other embodiments, the source/drain regions 110 may be of raised source/drain structures formed by means of selective epitaxial growth, wherein the top surface of the epitaxial portions is higher than the bottom of the gate stack (herein, the bottom of the gate indicates the interface between the gate stack and the semiconductor substrate 100). Optionally, prior to formation of the sidewall spacers 250, it is applicable to implement shallow doping to the substrates 100 on opposite sides of the dummy gate 220 so as to form source and drain extension regions; it is also applicable to implement Halo implantation to form Halo implantation regions. The type of dopants for the shallow doping is same as the type of the device, while the type of dopants for Halo implantation is opposite to the type of the device.

At step S104, the dummy gate structure 220 is removed.

Particularly, an etch stop layer 300 overlying the semiconductor structure may be formed on the semiconductor structure, as shown in FIG. 4. The etch stop layer 300 may be made of at least one material selected from a group consisting of Si₃N₄, Si₂N₂O, and SiC and/or another material as appropriate. The etch stop layer 300 may be formed through such a process as CVD, Physical Vapor Deposition (PVD), ALD and/or other process as appropriate. In an embodiment, the thickness of the etch stop layer 300 is in the range of 5 nm˜20 nm.

Preferably, an interlayer dielectric layer 400 is further formed on the etch stop layer 300. The interlayer dielectric layer 400 may be formed on the etch stop layer 300 by means of CVD, High-Density Plasma CVD, spin coating or other method as appropriate. The materials for the interlayer dielectric layer 400 may be at least one material selected from a group consisting of SiO₂, carbon-doped SiO₂, BPSG, PSG, UGS, Si₂N₂O, and a low-k material. The thickness of the interlayer dielectric layer 400 may be in the range of 40 nm˜150 nm, for example, 80 nm, 100 nm or 120 nm. As shown in FIG. 5, planarization process is implemented, such that the etch stop layer 300 on the gate stack is exposed and is at the same level as the interlayer dielectric layer 400 (herein, the term “at the same level” indicates the difference between the heights of the two objects is in the range of the permitted processing error).

It is noteworthy that the material for forming the etch stop layer 300 is more rigid than the material for forming the interlayer dielectric layer 400, such that the Chemical-mechanical Polish process shall be guaranteed to stop on the etch stop layer 300.

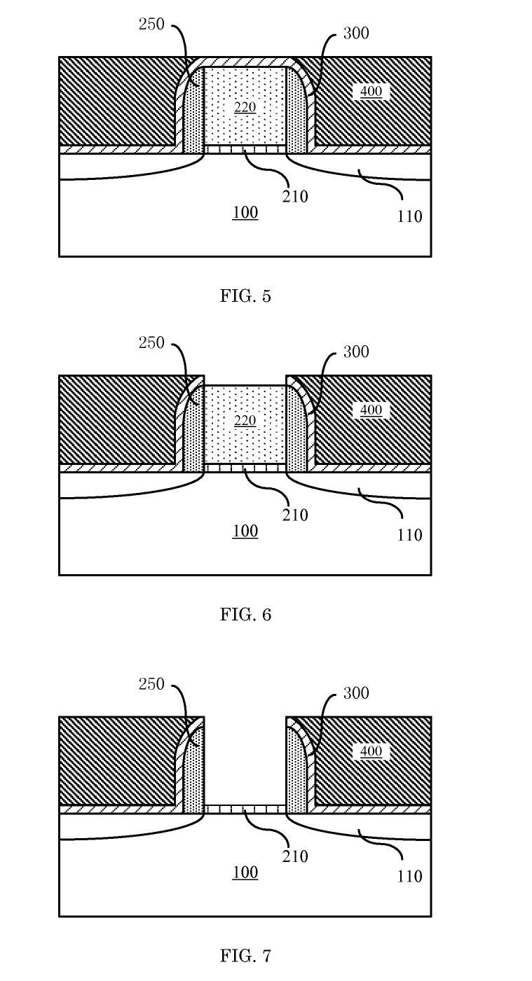

With reference to FIG. 6, the exposed etch stop layer 300 is selectively etched, so as to expose the dummy gate structure 220. The etch stop layer 300 may be removed through wet etching and/or dry etching. The wet etching includes using a solution with hydroxide (e.g. ammonium hydroxide), deionized water, or other etching solution as appropriate; the dry etching includes for example plasma etching. In other embodiments of the present invention, the etch stop layer 300 also may be planarized through CMP technique again till the dummy gate structure 220 is exposed; this is also capable of achieving the objective of removing the etch stop layer 300 above the dummy gate structure 220.

Next, the dummy gate structure 220 is removed, which accordingly is stopped on the gate dielectric layer 210, as shown in FIG. 7. The dummy gate structure 220 may be removed through wet etching and/or dry etching Plasma etching is used in an embodiment.

At step S105, annealing process is performed to activate the dopants in the source/drain regions 110. Annealing process is performed to the semiconductor structure formed previously, for example, laser annealing, flash annealing or the like may be implemented to activate the dopants in the semiconductor structure. In an embodiment, the semiconductor structure may be annealed by means of transient annealing process, for example, laser annealing performed under a temperature of 800-1100° C. It should be noted that the polymer materials is not able to sustain high temperatures, thus the semiconductor device must be processed again under a high temperature after the dummy gate structure 220 has been removed.

A metal gate is formed at step S106. The metal gate may only comprise a metal conductor layer 230, which is formed directly on the gate dielectric layer 210. The metal gate may further comprise a work function metal layer 240 and a metal conductor layer 230.

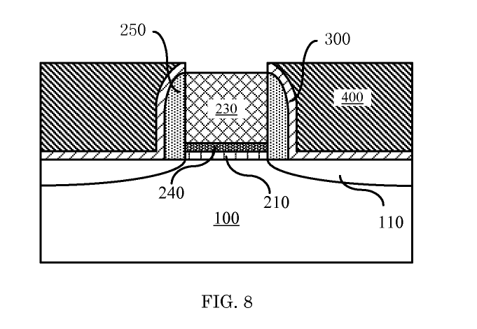

As shown in FIG. 8, the work function metal layer 240 is preferably deposited first on the gate dielectric layer 210, then the metal conductor layer 230 is formed on the work function metal layer 240. The work function metal layer 240 may be formed from TiN, TaN or the like, whose thickness is in the range of 3 nm-15 nm. The metal conductor layer 230 may be in a single layer or multi-layer structure, the material of which may be at least one material selected from a group consisting of TaN, TaC, TiN, TaAlN, TiAlN, MoAlN, TaTbN, TaErN, TaYbN, TaSiN, HfSiN, MoSiN, RuTaₓ and NiTaₓ, and whose thickness is in the range of 10 nm˜80 nm, for example, 30 nm or 50 nm.

In an embodiment, a work function metal layer 240 may optionally be formed on the gate dielectric layer 210 in the former step, then, the work function metal layer 240 is exposed after removing the dummy gate structure 220, and then a metal conductor layer 230 is formed on the work function metal layer 240 inside the opening previously formed. Since the work function metal layer 240 is formed on the gate dielectric layer 210, thus the metal conductor layer 230 is formed on the work function metal layer 240.

According to embodiments of the present invention, instead of forming gate sidewall spacers and the interlayer dielectric layer, the dummy gate structure may be removed directly after formation of source and drain, then a metal gate is formed anew on the gate dielectric layer after removing the dummy gate structure. Same as aforesaid technical solutions, this solution also is capable of implementing the Gate Replacement technology of the embodiments of the present invention.

As described above, the etching difficulty of removing a dummy gate structure is effectively alleviated through implementing the method for manufacturing a semiconductor structure provided by the present invention, in which a dummy gate structure is manufactured with a polymer material.

Although the exemplary embodiments and their advantages have been described in detail, it should be understood than various alternations, substitutions and modifications may be made to the embodiments without departing from the spirit of the present invention and the scope as defined by the appended claims. For other examples, it may be easily recognized by a person of ordinary skill in the art that the order of the process steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for manufacturing a semiconductor structure, comprising the following steps:
a) providing a substrate (100);
b) forming a gate dielectric layer (210) on the substrate (100), and forming a dummy gate structure (220) on the gate dielectric layer (210), wherein the dummy gate structure (220) is formed from a polymer material;
c) implanting dopants into portions of the substrates (100) on opposite sides of the dummy gate structure (220) to form source/drain regions (110);
d) removing the dummy gate structure (220);
e) annealing the source/drain regions (110) to activate the dopants after removal of the dummy gate structure; and
f) forming a metal gate.

2. The method of claim 1, wherein in step d), the dummy gate structure (220) is removed by dry etching.

3. The method of claim 1, wherein step f) comprises:
forming a work function metal layer (240) on the gate dielectric layer (210); and
forming a metal conductor layer (230) on the work function metal layer (240), wherein the work function metal layer (240) and the metal conductor layer (230) form the metal gate.

4. The method of claim 1, further comprising the following step after step b):
g) forming sidewall spacers (250) on sidewalls of the gate stack.

5. The method of claim 1, further comprising the following step prior to step d):
h) forming an etch stop layer (300) on the substrate (100) to cover the source/drain regions (110) and the gate stack on the substrate (100),
wherein, prior to removing the dummy gate structure (220) in step d), the method further comprises: etching away a portion of the etch stop layer (300) on the dummy gate structure (220) or planarizing the etch stop layer till the dummy gate (220) is exposed.

6. The method of claim 5, further comprising the following step after step h):
i) forming an interlayer dielectric layer (400) on the etch stop layer (300);
prior to the step of etching away the portion of the etch stop layer (300) on the dummy gate structure (220), the method further comprises: planarizing the interlayer dielectric layer (400) till the etch stop layer (300) is exposed.

7. The method of claim 1, wherein the polymer material comprises at least one material selected from a group consisting of Polymethylmethacrylate (PMMA), polycarbonate, SU-8, Polydimethylsiloxane (PDMS), Polyimide, and Parylene.

8. The method of claim 1, wherein the gate dielectric layer (210) comprises at least one material selected from a group consisting of SiO₂, Si₂N₂O, HfAlON, HfSiAlON, HfTaAlON, HfTiAlON, HfON, HfSiON, HfTaON, and HfTiON.

9. The method of claim 3, wherein the metal conductor layer (230) comprises at least one material selected from a group consisting of TaN, TiN, TaAlN, TiAlN, and MoAlN.
